(19) United States
(12) Patent Application Publication
(10) Pub. No.: US 2026/0118786 A1
(43) Pub. Date: Apr. 30, 2026

(54) METHOD AND STRUCTURE FOR LITHOGRAPHY ALIGNMENT

(71) Applicant: INSTITUTE OF MICROELECTRONICS, CHINESE ACADEMY OF SCIENCES, Beijing (CN)

(72) Inventors: Libin Zhang, Beijing (CN); Dinghai Rui, Beijing (CN); Yayi Wei, Beijing (CN); Yajuan Su, Beijing (CN)

(21) Appl. No.: 19/372,034

(22) Filed: Oct. 28, 2025

(30) Foreign Application Priority Data
Oct. 31, 2024 (CN) 202411540310.2

(51) Int. Cl. G03F 9/00; B24B 37/04; G01B 11/27; G03F 1/42; H01L 23/544

(52) U.S. Cl. CPC G03F 9/7076; B24B 37/042; G01B 11/272; G03F 1/42; G03F 9/7084; G03F 9/7088; H10W 46/00; H10W 46/301

(57) ABSTRACT

A method and a structure for lithography alignment. The method comprises: providing a first structure comprising a substrate and a mask layer located at a side of the substrate, a first pattern in the mask layer comprising a first groove, a second pattern serving as an alignment mark in the mask layer for lithography comprising a second groove; forming a metal layer filling the first groove fully and covering a sidewall and a bottom surface of the second groove, a thickness of the metal layer at the bottom surface of the second groove being less than a depth of the second groove; forming a first non-transparent layer having a first recess over the second pattern; forming a photoresist layer with a surface parallel to a surface of the substrate; and forming a second non-transparent layer with a surface parallel to the surface of the substrate.

The present disclosure claims the priority to Chinese Patent Application No. 202411540310.2, titled “METHOD FOR LITHOGRAPHY ALIGNMENT,” filed on Oct. 31, 2024, with the China National Intellectual Property Administration, the content of which is incorporated herein by reference.

### FIELD

The present disclosure relates to the technical field of semiconductor processing, and in particular to a method for lithography alignment.

### BACKGROUND

Development in manufacture of integrated circuits engenders increasingly smaller core structures, increasingly thinner films, and increasingly wider application of chemical mechanical polishing. Consequently, it is difficult to transfer morphological characteristics of patterns through the films when manufacturing the integrated circuits.

A non-transparent layer may be arranged between a layer carrying an alignment mark and a photoresist located above the layer. In such a case, it is rather challenging to detect the alignment mark in the beneath layer during a process of lithography alignment. Lithography equipment cannot proceed to following exposure processing when the alignment fails.

### SUMMARY

A method for lithography alignment is provided according to embodiments of the present disclosure. A position of an alignment mark can be precisely detected.

In a first aspect, a method for lithography alignment is provided according to embodiments of the present disclosure. The method comprises: providing a first structure comprising a substrate and a mask layer located at a side of the substrate, where a first pattern in the mask layer comprises a first groove, a second pattern in the mask layer comprises a second groove, and the second pattern serves as an alignment mark for lithography; forming a metal layer, where the metal layer fills the first groove fully and covers a sidewall and a bottom surface of the second groove, and a thickness of the metal layer at the bottom surface of the second groove is less than a depth of the second groove; forming a first non-transparent layer at a side the metal layer away from the substrate, where a surface of the first non-transparent layer away from the substrate has a first recess, and an orthographic projection of the first recess on the substrate is located within an orthographic projection of the second groove on the substrate; forming a photoresist layer at a side of the first non-transparent layer away from the substrate, where a surface of the photoresist layer away from the substrate is parallel to a surface of the substrate; and forming a second non-transparent layer at a side of the photoresist layer away from the substrate, where a surface of the second non-transparent layer away from the substrate is parallel to the surface of the substrate.

In an embodiment, the method further comprises determining a position of the alignment mark according to diffraction efficiency measured from a side of the second non-transparent layer away from the substrate.

In an embodiment, a width of the first groove is less than or equal to 200 nanometers.

In an embodiment, a width of the second groove is greater than or equal to 1 micrometer.

In an embodiment, a thickness of the mask layer ranges from 50 nanometers to 500 nanometers.

In an embodiment, forming the metal layer comprises: forming the metal layer at a side of the mask layer away from the substrate, where a surface of the metal layer away from the substrate comprises a second recess, and an orthographic projection of the second recess on the substrate is located within the orthographic projection of the second groove on the substrate; and planarizing the metal layer through chemical mechanical polishing (CMP).

In an embodiment, the first structure further comprises a first protective layer located between the substrate and the mask layer.

In an embodiment, before forming the first non-transparent layer, the method further comprises: forming a second protective layer at the side of the metal layer away from the substrate, where a surface of the second protective layer away from the substrate has a third recess, and an orthographic projection of the third recess on the substrate is located within the orthographic projection of the second groove on the substrate.

In an embodiment, before forming the photoresist layer, the method further comprises: forming a dielectric material layer at the side of the first non-transparent layer away from the substrate, where a surface of the dielectric material layer away from the substrate has a fourth recess, an orthographic projection of the fourth recess on the substrate is located within the orthographic projection of the second groove on the substrate, and a refractive index of the dielectric material layer is different from a refractive index of the first non-transparent layer.

In an embodiment, a material of the metal layer comprises copper or aluminum.

In an embodiment, a material of the first non-transparent layer comprises silver or aluminum, and a material of the second non-transparent layer comprises aluminum or silver.

In an embodiment, the first pattern is a pattern in a core feature region, and the first pattern does not serve as another alignment mark for lithography.

In a second aspect, a structure for lithography alignment is provided according to embodiments of the present disclosure. The structure comprises: a first structure, comprising a substrate and a mask layer located at a side of the substrate, where a first pattern in the mask layer comprises a first groove, a second pattern in the mask layer comprises a second groove, and the second pattern serves as an alignment mark for lithography; a metal layer, filling the first groove fully and covering a sidewall and a bottom surface of the second groove, where a thickness of the metal layer at the bottom surface of the second groove is less than a depth of the second groove; a first non-transparent layer, located at a side of the metal layer away from the substrate, where a surface of the first non-transparent layer away from the substrate has a first recess, and an orthographic projection of the first recess on the substrate is located within an orthographic projection of the second groove on the substrate; a photoresist layer, located at a side of the first non-transparent layer away from the substrate, where a surface of the photoresist layer away from the substrate is parallel to a surface of the substrate; and a second non-transparent layer, located at a side of the photoresist layer away from the substrate, where a surface of the second non-transparent layer away from the substrate is parallel to the surface of the substrate.

Herein the method for lithography alignment is provided. The mask layer has the first groove and the second groove. During fabrication, the metal layer fills the first groove fully and covers the sidewall and the bottom surface of the second groove, and the thickness of the metal layer at the bottom surface of the second groove is smaller than the depth of the second groove. Accordingly, the metal layer is conformal to the second groove is morphology. The orthographic projection of the first recess of the first non-transparent layer on the substrate is located within the orthographic projection of the second groove on the substrate, and hence a part of the first non-transparent layer is also conformal to the second groove is morphology. Then, the photoresist layer and the second non-transparent layer are sequentially formed, and the surface of each of these two layers away from the substrate is parallel to the surface of the substrate. Accordingly, the photoresist layer above the first pattern is thinner than the photoresist layer above the second pattern that serves as the alignment mark. Different thicknesses of the photoresist layer would generate different response signals during measurement of diffraction efficiency, and hence the position of the alignment mark can be accurately determined.

### BRIEF DESCRIPTION OF THE DRAWINGS

Features, advantages, and aspects of embodiments of the present disclosure will be illustrated in conjunction with drawings and embodiments as follows. The same or similar reference numerals throughout the drawings represent the same or similar elements. The drawings are schematic, and components and elements in the drawings may not be depicted to scale.

FIG. 1 is a schematic flowchart of a method for lithography alignment according to an embodiment of the present disclosure;

FIG. 2 to FIG. 9 are schematic diagrams of structures processed in a method for lithography alignment according to an embodiment of the present disclosure.

FIG. 10 is a schematic graph of a relationship between normalized diffraction efficiency with respect to thickness of a mask layer according to an embodiment of the present disclosure.

FIG. 11 is a schematic diagram of a structure for lithography alignment according to an embodiment of the present disclosure.

### DETAILED DESCRIPTION

Hereinafter embodiments of the present disclosure will be described in conjunction with the drawings for embodiments of the present disclosure. Some terms used herein are only for explaining specific embodiments of the present disclosure, rather than limiting the present disclosure. Those skilled in the art can appreciate that technical solutions provided herein are applicable to similar technical problems even considering development of technologies and emergence of new scenarios.

Herein terms concerning directions are utilized on a basis of relative positional relationships as depicted in the drawings and should not be construed as absolute limitation on the present disclosure.

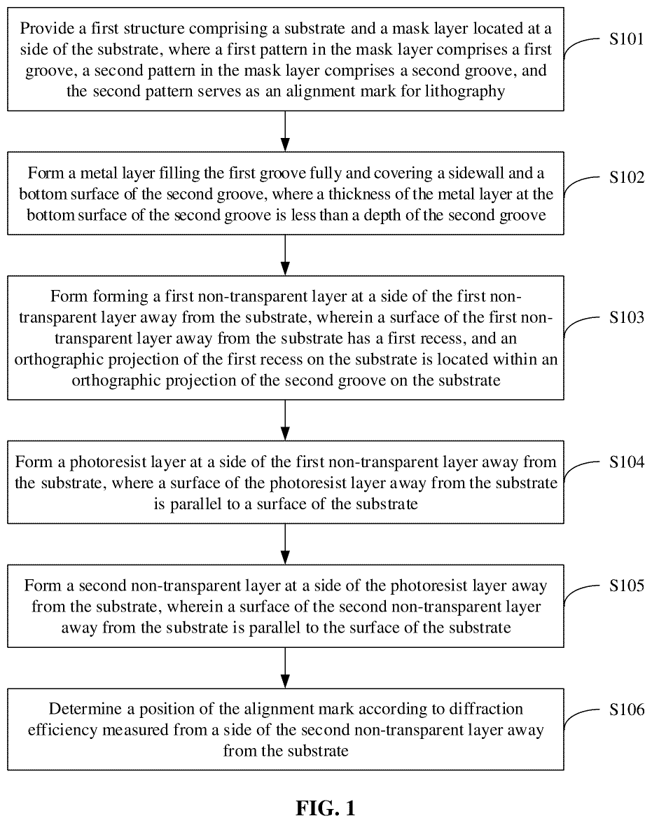

Reference is made to FIG. 1, which is a schematic flowchart of a method for lithography alignment according to an embodiment of the present disclosure. A method for lithography alignment comprises the following steps S101 to S106.

In step S101, a first structure comprising a substrate 11 and a mask layer 12 located at a side of the substrate 11 is provided, where a first pattern in the mask layer comprises a first groove 13, a second pattern in the mask layer comprises a second groove 13, and the second pattern serves as an alignment mark for lithography. Reference is made to FIG. 2.

In an embodiment, the first pattern is a pattern in a core feature region. The first pattern may be no alignment mark for lithography.

The mask layer 12 may comprise, but is not limited to, a hard mask layer. In an embodiment, a thickness of the mask layer ranges from 50 nanometers to 500 nanometers. For example, the thickness of the mask layer 12 may be 50 nanometers, 78 nanometers, 200 nanometers, 264 nanometers, or 500 nanometers. In an embodiment, a width W01 of the first groove 13 is less than or equal to 200 nanometers. For example, the width W01 of the first groove 13 is 200 nanometers, 146 nanometers, or 75 nanometers. In an embodiment, a width W02 of the second groove 14 is greater than or equal to 1 micrometer. For example, the width W02 of the second groove 14 may be 1 micrometer, 3.5 micrometers, or 8 micrometers.

When there is a groove smaller than, for example, 1 micrometer, in a pattern comprising the alignment mark, such pattern in the mask layer 12 may be partitioned more finely with reference to a dimension of the first pattern. For example, a part of the pattern other than the second groove 14 may be divided into sub-patterns, and the single sub-pattern may serve as the first pattern and comprise a groove identical or substantially identical to the first groove 13 in width.

A material of the mask layer 12 may comprise, but is not limited to, a dielectric material such as silicon oxide or silicon nitride. The material is required to have good electrical insulation. The mask layer 12 may serve as a layer for blocking metal atoms.

Reference is made to FIG. 3. In an embodiment, the first structure further comprises a first protective layer 15 located between the substrate 11 and the mask layer 12.

Metallic layer(s) would be formed in subsequent processes a protective layer, and hence a protective layer, i.e., the first protective layer 15, is provided between the substrate 11 and the mask layer 12 to block diffusion of the metal atoms from the metallic layer(s) and ensure the quality of the metallic layer(s). That is, the protective layer is configured for protecting a bottom of the metal layer.

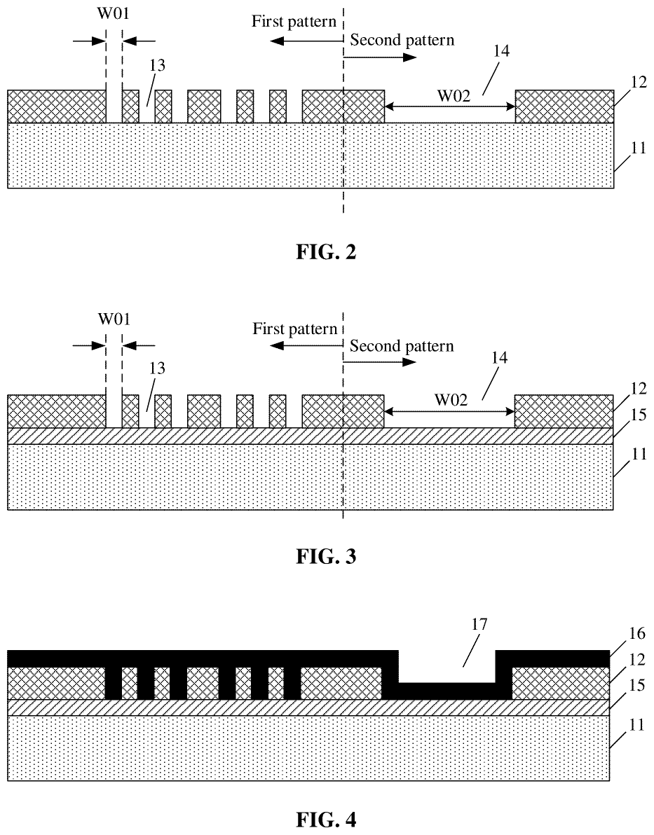

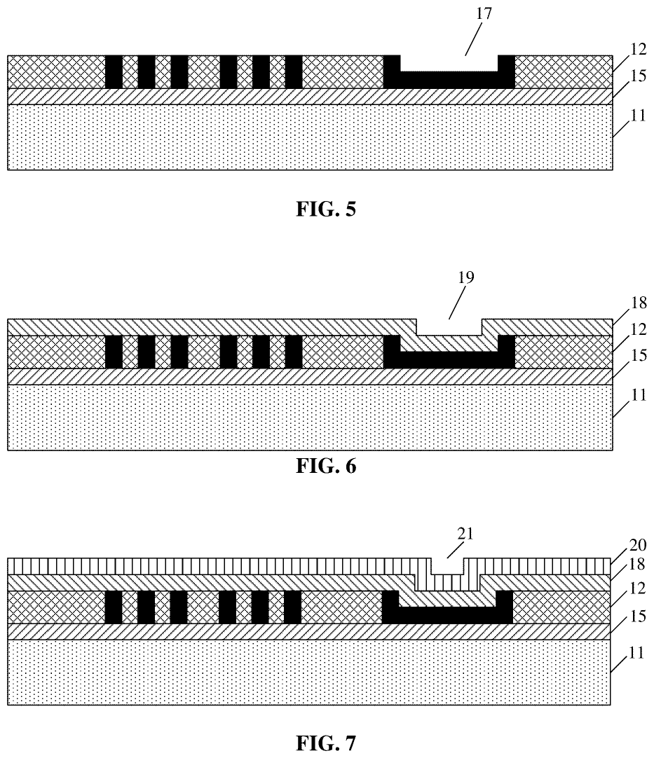

In step S102, a metal layer 16 is formed, where the metal layer 16 fills the first groove 13 fully and covers a sidewall and a bottom surface of the second groove 14, and a thickness of the metal layer 16 at the bottom surface of the second groove 14 is less than a depth of the second groove 14. Reference is made to FIG. 4 and FIG. 5.

In an embodiment, the metal layer 16 is formed through a following process.

Reference is made to FIG. 4. The metal layer 16 is first formed at a side of the mask layer 12 away from the substrate 11. A surface of the metal layer 16 away from the substrate 11 has a second recess 17, and an orthographic projection of the second recess 17 on the substrate 11 is located within an orthographic projection of the second groove 14 on the substrate 11.

Reference is made to FIG. 5. The formed metal layer 16 is then planarized through, for example, chemical mechanical polishing (CMP). A degree of the planarization is controlled such that the metal layer 16 fills the first groove 13 fully and covers the sidewall and the bottom surface of the second groove 14, and the thickness of the metal layer 16 at the bottom surface of the second groove 14 is less than the depth of the second groove 14.

A material of the metal layer 16 may comprise, but is not limited to, copper or aluminum. The metal layer 16 may be formed through, but not limited to, electroplating, and the thickness of the metal layer 16 in different regions is controlled through regulating parameters of the electroplating. For example, duration of the electroplating is adjusted to control morphology of the metal layer 16 covering the first structure precisely, such that a conformal coverage as shown in FIG. 4 is achieved. That is, the region having the first pattern is well filled, whole morphology of the region having the second pattern is maintained. Theoretically, in a cross-sectional view, a surface contour of the second recess 17 and that of the second groove 14 are similar shapes, while a width of the second recess 17 is smaller than that of the second groove 14.

Reference is further made to FIG. 4. The metal layer 16 may be deposited with a margin in thickness during the electroplating to ensure that the metal layer 16 fills the first groove 13 fully. In this case, the metal layer 16 may cover a top surface of the mask layer 12 completely.

Reference is further made to FIG. 5. Afterwards, the metal layer 16 is planarized through, for example, the CMP to remove the metal layer 16 on the top surface of the mask layer 12. The remaining metal layer 16 fills the first groove 13 fully and covers the sidewall and the bottom surface of the second groove 14, and the thickness of the remaining metal layer 16 at the bottom surface of the second groove 14 is less than the depth of the second groove 14. Thus, the resultant film structure has different characteristics at different portions.

The different characteristics refers to following differences. The metal layer 16 on the first pattern fills the first groove 13 fully, that is, the thickness of the metal layer 16 in the first groove 13 is equal to the depth of the first groove 13. In comparison, the metal layer 16 in the second pattern covers the sidewall and the bottom surface of the second groove 14, and the thickness of the metal layer 16 at the bottom surface of the second groove 14 is less than the depth of the second groove 14. That is, a conformal structure with stepped morphology is formed in the second groove 14.

Reference is made to FIG. 6. In an embodiment, the method comprises a following step before forming a first non-transparent layer. A second protective layer 18 is formed, where a surface of the second protective layer 18 away from the substrate 11 has a third recess 19, and an orthographic projection of the third recess 19 on the substrate 11 is located within the orthographic projection of the second groove 14 on the substrate 11.

After the metal layer 16 has been prepared, a protective layer, i.e., the second protective layer 18, is provided on the metal layer 16 to block diffusion of the metal atoms in the metal layer 16 and film quality of the metal layer 16. That is, the second protective layer 18 is configured for protecting a top of the metal layer 16.

The metal layer 16 can be thoroughly protected when both the first protective layer 15 and the second protective layer 18 are provided on a basis of the mask layer 12. In this case, the film quality of the metal layer 16 can be greatly improved.

Due to the morphology of the layers as shown in FIG. 5, the surface of the second protective layer 18 away from the substrate 11 has the third recess 19 which is conformal to the beneath structure, as shown in FIG. 6. That is, the second protective layer 18 above the first pattern is planar while the second protective layer 18 above the second pattern is conformal to the second groove 14. Theoretically, in a cross-sectional view, a surface contour of the third recess 19 and that of the second groove 14 are similar shapes, while a width of the third recess 19 is smaller than that of the second groove 14 and also smaller than that of the second recess 17.

In an embodiment, a thickness of the second protective layer 18 ranges from 5 nanometers to 200 nanometers. For example, the thickness of the second protective layer 18 may be 5 nanometers, 60 nanometers, 124 nanometers, or 200 nanometers.

In step S103, a first non-transparent layer 20 is formed at a side of the metal layer 16 away from the substrate 11, where a surface of the first non-transparent layer 20 away from the substrate 11 has a first recess 21, and an orthographic projection of the first recess 21 on the substrate 11 is located within the orthographic projection of the second groove 14 on the substrate 11. Reference is made to FIG. 7.

A material of the first non-transparent layer 20 may comprise, but is not limited to, silver or aluminum. The first non-transparent layer 20 may be fabricated through metal sputtering. In an embodiment, a thickness of the first non-transparent layer 20 is less than or equal to 50 nanometers.

Due to the morphology of the layers as shown in FIG. 6, the surface of the first non-transparent layer 20 away from the substrate 11 has the first recess 21 which is conformal to the beneath structure, as shown in FIG. 7. That is, the first non-transparent layer 20 above the first pattern is planar while the first non-transparent layer 20 above the second pattern is conformal to the second groove 14. Theoretically, in a cross-sectional view, a surface contour of the first recess 21 and that of the second groove 14 are similar shapes, while a width of the first recess 21 is smaller than that of the second groove 14, smaller than that of the second recess 17, and smaller than that of the third recess 19.

In S104, a photoresist layer 22 is formed at a side of the first non-transparent layer 20 away from the substrate 11, where a surface of the photoresist layer 22 away from the substrate 11 is parallel to a surface of the substrate 11. Reference is made to FIG. 8.

In an embodiment, the photoresist layer 22 is prepared through spin-coating, and a top surface of the prepared photoresist layer 22 is level. The surface of the photoresist layer 22 away from the substrate 11 being parallel to the surface of the substrate 11 renders the thickness of the photoresist layer 22 over the first pattern thinner than that over the second pattern.

In S105, a second non-transparent layer 23 is formed at a side of the photoresist layer 22 away from the substrate 11, where a surface of the second non-transparent layer 23 away from the substrate 11 is parallel to the surface of the substrate 11.

A material of the second non-transparent layer 23 may comprise, but is not limited to, silver or aluminum. The second non-transparent layer 23 may be fabricated through metal sputtering. In an embodiment, a thickness of the second non-transparent layer 23 is less than or equal to 50 nanometers.

In an embodiment, the thickness of the first non-transparent layer 20 and the thickness of the second non-transparent layer 23 are both 30 nanometers, and the thickness of the photoresist layer 22 is 50 nanometers.

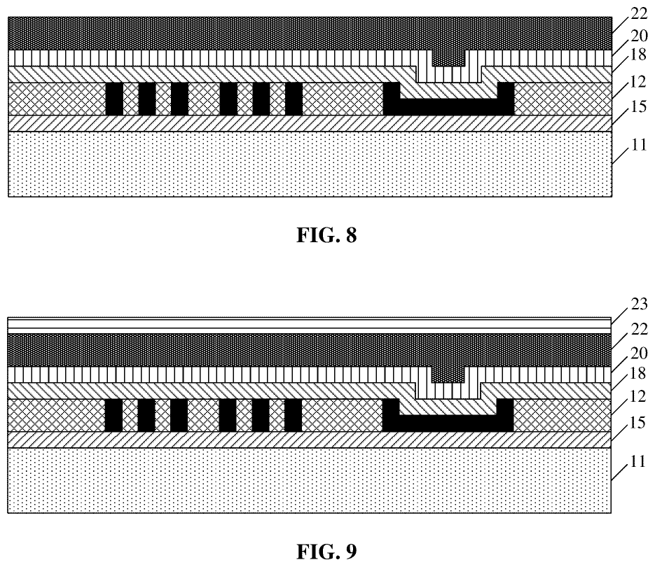

As shown in FIG. 9, a sandwich structure is formed by the first non-transparent layer 20, the photoresist layer 22, and the second non-transparent layer 23, and the photoresist layer 22 has different characteristics between the first pattern and the second pattern. The different characteristics refer to that the photoresist layer 22 over the first pattern is thinner than that over the second pattern. Hence, when diffraction efficiency is measured in a subsequent step, the photoresist layer 22 of different thicknesses would generate different response signals, and the position of the alignment mark can thus be accurately determined.

In step S106, a position of the alignment mark is determined according to diffraction efficiency measured from a side of the second non-transparent layer 23 away from the substrate 11.

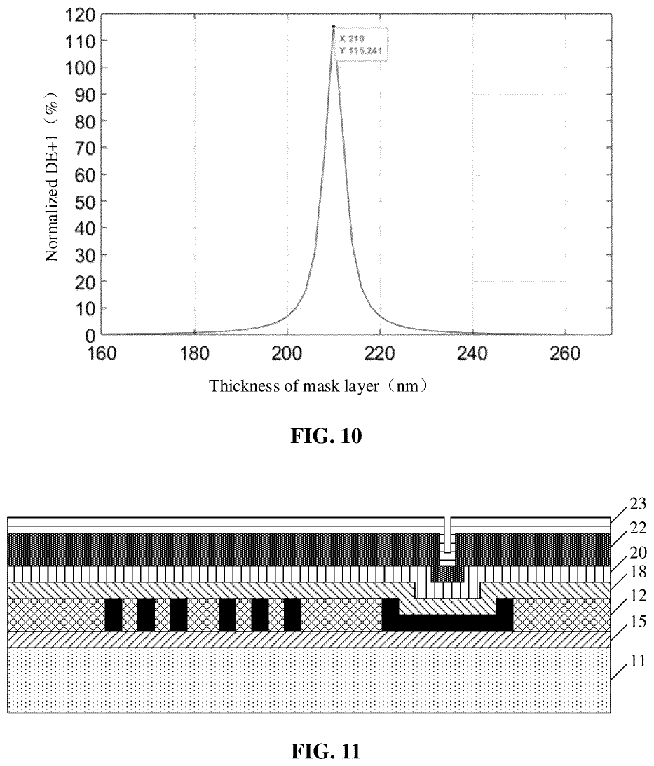

Reference is made to FIG. 10, which is a schematic graph of normalized diffraction efficiency with respect to thickness of a mask layer according to an embodiment of the present disclosure. As discussed above, in the sandwich structure, the photoresist layer 22 has different characteristics between the first pattern and the second pattern, that is, the photoresist layer 22 over the first pattern is thinner than that over the second pattern. Hence, the response signal generated by the photoresist layer 22 is different due to the different thickness during measurement of the diffraction efficiency. Hence, the thickness of the mask layer 12 may be optimized to regulate the response signal to achieve accurate positioning on the alignment mark.

The measurement on diffraction efficiency refers to detecting a ratio of intensity in a designated diffraction beam, especially the +1-order diffraction beam. When normalized diffraction efficiency is used for distinguishing the alignment mark, the diffraction efficiency is usually required to exceed 0.1%. As shown in FIG. 10, the diffraction efficiency changes with the thickness of the mask layer 12. The diffraction efficiency reaches a maximum of 115% when the thickness of the mask layer 12 is 210 nanometers. Here a light wavelength used in diffraction efficiency measurement is 633 nanometers. The diffraction efficiency is normalized with reference to the first order diffraction beam under a grating period of 16 μm and a grating depth of a quarter of the wavelength (e.g., the grating depth is 158.25 nanometers when the light wavelength is 633 nanometers) on a surface of silicon. The light having a wavelength ranging from 400 nanometers to 900 nanometers may be utilized for the measurement. When the light is changed from one wavelength to another, the thickness of the mask layer 12 may be re-optimized.

Reference is further made to FIG. 10. When the thickness of the mask layer 12 is greater than 147 nanometers and less than 268 nanometers, the +1-order diffraction efficiency (DE+1) exceeds 0.1%. When the thickness of the mask layer 12 is greater than 184 nanometers and is less than 236 nanometers, the DE+1 exceeds 1%. Thus, the normalized diffraction efficiency can satisfy a level of 0.1% when the thickness of the mask layer 12 is controlled within a range from 147 nanometers to 268 nanometers, and the normalized diffraction efficiency can satisfy a level of 1% when the thickness of the mask layer 12 is controlled within a range from 184 nanometers to 236 nanometers.

The above technical solutions can be utilized to address the issue of difficulties in detecting the alignment mark in a beneath layer. It is ensured that the photoresist layer 22 over the first pattern and the photoresist layer 22 over the second pattern has different thickness, and the thickness of the mask layer 12 can be optimized to achieve excellent alignment efficiency.

Moreover, a quality of the metal layer 16 filling the first pattern and a conformal characteristic of the layers over the alignment mark are both guaranteed. Hence, imaging quality of a region (e.g., the core feature region) having the first pattern are not affected, and it is not necessary to perform additional processing on a region having the alignment mark. For example, it is not necessary to remove the non-transparent layer(s) through an additional lithography process.

Reference is made to FIG. 11, which is a schematic diagram of a structure for lithography alignment according to an embodiment of the present disclosure. In an embodiment, a dimension of the second groove 14 in the second pattern is at a level of micrometers, such that the fabricated photoresist layer 22 is conformal to the second groove 14, and the fabricated second non-transparent layer 23 is also conformal to the second groove 14. When the above conformality features can be clearly distinguished, the position of the alignment mark pattern can be directly determined, and hence it is not necessary to further optimize the thickness of the mask layer 12.

In an embodiment, the method further comprises a following step before forming the photoresist layer 22. A dielectric material layer is formed, where a surface of the dielectric material layer away from the has a fourth recess recessed toward the substrate 11, an orthographic projection of the fourth recess on the substrate 11 is located within the orthographic projection of the second groove 14 on the substrate 11, and a refractive index of the dielectric material layer is different from a refractive index of the first non-transparent layer 20.

After the first non-transparent layer 20 is fabricated, a layer of a different material may be deposited and then planarized through CMP to achieve a flat surface. Afterwards, the photoresist layer 22 and the second non-transparent layer 23 are fabricated. The refractive index of the dielectric material layer is different from that of the first non-transparent layer 20, such that a difference can be introduced into the optical response signal. Hence, the position of the alignment mark pattern can be determined more accurately according to measurement of the diffraction efficiency.

Hereinabove details of the method for lithography alignment are illustrated according to embodiments of the present disclosure. The principles and implementations of the present disclosure are described with specific examples. The above description of embodiments is only used to facilitate understanding of the method and the core idea of the present disclosure. In addition, those skilled in the art may make variations to implementations and an application scope as disclosed above according to a concept of the present disclosure. Therefore, the specification should not be construed as a limitation to the present disclosure.

A structure for lithography alignment is further provided according to embodiments of the present disclosure. The structure comprises: a first structure, a metal layer, a first non-transparent layer, a photoresist layer, and a second non-transparent layer.

The first structure comprises a substrate and a mask layer located at a side of the substrate, where a first pattern in the mask layer comprises a first groove, a second pattern in the mask layer comprises a second groove, and the second pattern serves as an alignment mark for lithography;

The metal layer fills the first groove fully and covers a sidewall and a bottom surface of the second groove, where a thickness of the metal layer at the bottom surface of the second groove is less than a depth of the second groove;

The first non-transparent layer is located at a side of the metal layer away from the substrate, where a surface of the first non-transparent layer away from the substrate has a first recess, and an orthographic projection of the first recess on the substrate is located within an orthographic projection of the second groove on the substrate;

The photoresist layer is located at a side of the first non-transparent layer away from the substrate, where a surface of the photoresist layer away from the substrate is parallel to a surface of the substrate.

The second non-transparent layer is located at a side of the photoresist layer away from the substrate, where a surface of the second non-transparent layer away from the substrate is parallel to the surface of the substrate.

Details of the layers in the above structure may refer to the above method embodiments and would not be repeated herein.

The embodiments of the present disclosure are described in a progressive manner, and each embodiment places emphasis on the difference from other embodiments.

The relationship terms such as “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article, or a device including a series of elements include not only the disclosed elements but also other elements that are not clearly enumerated, or further include inherent elements of the process, the method, the article, or the device. Unless expressively limited, the statement “including a . . . ” does not exclude the case that other similar elements may exist in the process, the method, the article, or the device other than enumerated elements.

According to the description of the disclosed embodiments, those skilled in the art can implement or use the present disclosure. Various modifications made to these embodiments may be obvious to those skilled in the art, and the general principle defined herein may be implemented in other embodiments without departing from the spirit or scope of the present disclosure. Therefore, the present disclosure is not limited to the embodiments described herein but conforms to a widest scope in accordance with principles and novel features disclosed in the present disclosure.

1. A method for lithography alignment, comprising:
providing a first structure comprising a substrate and a mask layer located at a side of the substrate, wherein a first pattern in the mask layer comprises a first groove, a second pattern in the mask layer comprises a second groove, and the second pattern serves as an alignment mark for lithography;
forming a metal layer, wherein the metal layer fills the first groove fully and covers a sidewall and a bottom surface of the second groove, and a thickness of the metal layer at the bottom surface of the second groove is less than a depth of the second groove;
forming a first non-transparent layer at a side of the metal layer away from the substrate, wherein a surface of the first non-transparent layer away from the substrate has a first recess, and an orthographic projection of the first recess on the substrate is located within an orthographic projection of the second groove on the substrate;
forming a photoresist layer at a side of the first non-transparent layer away from the substrate, wherein a surface of the photoresist layer away from the substrate is parallel to a surface of the substrate; and
forming a second non-transparent layer at a side of the photoresist layer away from the substrate, wherein a surface of the second non-transparent layer away from the substrate is parallel to the surface of the substrate.

2. The method according to claim 1, further comprising:
determining a position of the alignment mark according to diffraction efficiency measured from a side of the second non-transparent layer away from the substrate.

3. The method according to claim 1, wherein a width of the first groove is less than or equal to 200 nanometers.

4. The method according to claim 1, wherein a width of the second groove is greater than or equal to 1 micrometer.

5. The method according to claim 1, wherein a thickness of the mask layer ranges from 50 nanometers to 500 nanometers.

6. The method according to claim 1, wherein forming the metal layer comprises:
forming the metal layer at a side of the mask layer away from the substrate, wherein a surface of the metal layer away from the substrate comprises a second recess, and an orthographic projection of the second recess on the substrate is located within the orthographic projection of the second groove on the substrate; and
planarizing the metal layer through chemical mechanical polishing.

7. The method according to claim 1, wherein the first structure further comprises a first protective layer located between the substrate and the mask layer.

8. The method according to claim 1, wherein before forming the first non-transparent layer, the method further comprises:
forming a second protective layer at the side of the metal layer away from the substrate, wherein a surface of the second protective layer away from the substrate has a third recess, and an orthographic projection of the third recess on the substrate is located within the orthographic projection of the second groove on the substrate.

9. The method according to claim 1, wherein before forming the photoresist layer, the method further comprises:
forming a dielectric material layer at the side of the first non-transparent layer away from the substrate, wherein a surface of the dielectric material layer away from the substrate has a fourth recess, an orthographic projection of the fourth recess on the substrate is located within the orthographic projection of the second groove on the substrate, and a refractive index of the dielectric material layer is different from a refractive index of the first non-transparent layer.

10. The method according to claim 1, wherein a material of the metal layer comprises copper or aluminum.

11. The method according to claim 1, wherein a material of the first non-transparent layer comprises silver or aluminum, and a material of the second non-transparent layer comprises aluminum or silver.

12. The method according to claim 1, wherein the first pattern is a pattern in a core feature region, and the first pattern does not serve as another alignment mark for lithography.

13. A structure for lithography alignment, comprising:
a first structure, comprising a substrate and a mask layer located at a side of the substrate, wherein a first pattern in the mask layer comprises a first groove, a second pattern in the mask layer comprises a second groove, and the second pattern serves as an alignment mark for lithography;
a metal layer, filling the first groove fully and covering a sidewall and a bottom surface of the second groove, wherein a thickness of the metal layer at the bottom surface of the second groove is less than a depth of the second groove;
a first non-transparent layer, located at a side of the metal layer away from the substrate, wherein a surface of the first non-transparent layer away from the substrate has a first recess, and an orthographic projection of the first recess on the substrate is located within an orthographic projection of the second groove on the substrate;
a photoresist layer, located at a side of the first non-transparent layer away from the substrate, wherein a surface of the photoresist layer away from the substrate is parallel to a surface of the substrate; and
a second non-transparent layer, located at a side of the photoresist layer away from the substrate, wherein a surface of the second non-transparent layer away from the substrate is parallel to the surface of the substrate.

14. The structure according to claim 13, wherein the first structure further comprises a first protective layer located between the substrate and the mask layer.

15. The structure according to claim 13, further comprising:
a second protective layer, located between the metal layer and the first non-transparent layer, wherein a surface of the second protective layer away from the substrate has a third recess, and an orthographic projection of the third recess on the substrate is located within the orthographic projection of the second groove on the substrate.

16. The structure according to claim 13, further comprising:
a dielectric material layer, located between the first non-transparent layer and the photoresist layer, wherein a surface of the dielectric material layer away from the substrate has a fourth recess, an orthographic projection of the fourth recess on the substrate is located within the orthographic projection of the second groove on the substrate, and a refractive index of the dielectric material layer is different from a refractive index of the first non-transparent layer.

17. The structure according to claim 13, wherein the first pattern is a pattern in a core feature region, and the first pattern does not serve as another alignment mark for lithography.
